(19) United States
(12) Patent Application Publication
(10) Pub. No.: US 2026/0106436 A1
(43) Pub. Date: Apr. 16, 2026

(54) LIGHT-EMITTING DIODE AND LIGHT-EMITTING DEVICE

(71) Applicant: QUANZHOU SANAN SEMICONDUCTOR TECHNOLOGY CO., LTD., Quanzhou (CN)

(72) Inventors: Yue ZENG, quanzhou (CN); Shaohua HUANG, quanzhou (CN); Mingkui LI, Quanzhou (CN); Tungwei YEN, Quanzhou (CN); Shaowei CAO, Quanzhou (CN); Hanzhi HAUNG, Quanzhou (CN); Tao YE, Quanzhou (CN)

(21) Appl. No.: 19/382,304

(22) Filed: Nov. 7, 2025

Related U.S. Application Data
(63) Continuation of application No. PCT/CN2024/092514, filed on May 11, 2024.

(51) Int. Cl. H01S 5/223

(52) U.S. Cl. CPC H01S 5/2238

(57) ABSTRACT

A semiconductor laser element includes: a substrate and a semiconductor stack including a first semiconductor layer, an active layer, and a second semiconductor layer sequentially stacked. A ridge is formed on a surface of the second semiconductor layer. The semiconductor stack includes: a first mesa connected to a side surface of the ridge, a second mesa adjacent to a first side surface or a second side surface of the substrate, the first mesa exposes a portion of a surface of the second semiconductor layer, and the second mesa exposes a portion of a surface of the first semiconductor layer. The semiconductor stack further includes: a connection surface exposing a portion of the surface of the first semiconductor layer, a first segment sidewall located between the first mesa and the connection surface, and a second segment sidewall located between the second mesa and the connection surface.

### CROSS-REFERENCE TO RELATED APPLICATION

This application is a continuation of International Application No. PCT/CN2024/092514, filed on May 11, 2024. The international Application claims priority to a Chinese patent application No. CN202310516004.4, filed on May 9, 2024. The entire contents of the above-mentioned applications are hereby incorporated by reference.

### TECHNICAL FIELD

The disclosure relates to the field of semiconductor technologies, and particularly to a semiconductor laser element.

### BACKGROUND

Semiconductor light-emitting devices, such as light-emitting diodes (LEDs) and semiconductor laser elements, have attracted increasing attention to their research and market applications due to their excellent luminescent properties. For instance, the semiconductor laser elements have achieved extensive research progress and widespread market applications, especially in laser displays and laser projection systems.

In semiconductor laser elements, particularly in vertical-cavity surface-emitting lasers (VCSELs), internal electric fields can arise due to the lattice structure and doping characteristics of gallium nitride (GaN) materials. When the GaN materials undergo curved surface deformation, they are prone to band offset and alterations in electronic structure, leading to changes in the distribution of internal electric fields. Consequently, the electrical and optical properties of the material may be modified. In the related art, etching the semiconductor stack forms a first mesa, a second mesa, and sidewalls connecting the first and second mesas. The junction between the second mesa and the sidewalls forms a curved surface. Due to factors such as the internal electric fields in the GaN materials, this curved surface may adversely affect the breakdown voltage of the semiconductor laser element, increasing the risk of leakage current.

### SUMMARY

In a first aspect of the disclosure, a semiconductor laser element is provided, including: a substrate and a semiconductor stack.

The substrate has a first surface and a first side surface and a second side surface located on opposite sides of the substrate, and the first side surface and the second side surface extends along a first direction.

The semiconductor stack is formed on the first surface of the substrate, including a first semiconductor layer, an active layer, and a second semiconductor layer stacked sequentially. A ridge is formed on a surface of the second semiconductor layer, the ridge has an upper surface and a side surface adjacent to the upper surface, and the ridge extends along the first direction.

The semiconductor stack further includes a first mesa connected to the side surface of the ridge and a second mesa adjacent to the first side surface or the second side surface of the substrate, the first mesa exposes a portion of a surface of the second semiconductor layer, and the second mesa exposes a portion of a surface of the first semiconductor layer.

The semiconductor stack further includes a connection surface exposing a portion of the surface of the first semiconductor layer, a first segment sidewall, and a second segment sidewall. The first segment sidewall is located between the first mesa and the connection surface, the second segment sidewall is located between the second mesa and the connection surface, and a length of the first segment sidewall is greater than or equal to a length of the second segment sidewall.

In an embodiment, a ratio of the length of the first segment sidewall to the length of the second segment sidewall is greater than 5:1.

In an embodiment, in a cross-sectional view of the semiconductor laser element, an angle between the first segment sidewall and the connection surface is a first angle α1, an angle between the second segment sidewall and the second mesa is a second angle α2, and the first angle α1 is different from the second angle α2.

In an embodiment, the first angle α1 is greater than or equal to the second angle α2.

In an embodiment, the first angle α1 is greater than or equal to 90°, and the second angle α2 is greater than or equal to 80°.

The disclosure provides another semiconductor laser element, including: a substrate and a semiconductor stack.

The substrate has a first surface, and a first side surface and a second side surface located on opposite sides of the substrate, and the first side surface and the second side surface extending along a first direction.

The semiconductor stack is formed on the first surface of the substrate, including a first semiconductor layer, an active layer, and a second semiconductor layer stacked sequentially. A ridge is formed on a surface of the second semiconductor layer, the ridge has an upper surface and a side surface adjacent to the upper surface, and the ridge extends along the first direction.

The semiconductor stack further includes a first mesa connected to the side surface of the ridge and a second mesa adjacent to the first side surface or the second side surface of the substrate, the first mesa exposes a portion of a surface of the second semiconductor layer, and the second mesa exposes a portion of a surface of the first semiconductor layer.

The semiconductor stack further includes a connection surface exposing a portion of the surface of the first semiconductor layer, a first segment sidewall, and a second segment sidewall. The first segment sidewall is located between the first mesa and the connection surface, the second segment sidewall is located between the second mesa and the connection surface, an angle between the first segment sidewall and the connection surface is a first angle α1, an angle between the second segment sidewall and the second mesa is a second angle α2, and the first angle α1 is different from the second angle α2.

In an embodiment, the first angle α1 is greater than or equal to the second angle α2.

In an embodiment, the first angle α1 is greater than or equal to 90°, and the second angle α2 is greater than or equal to 80°.

In an embodiment, taking a second surface of the substrate as a horizontal plane, the upper surface of the ridge is higher than the first mesa, and the first mesa is higher than the second mesa.

In an embodiment, taking the second surface of the substrate as the horizontal plane, a height of the connection surface is between a height of the first mesa and a height of the second mesa.

In an embodiment, in a cross-sectional view of the semiconductor laser element, a width of the first mesa is greater than a width of the second mesa, and the width of the second mesa is greater than a width of the connection surface.

In an embodiment, the semiconductor stack further includes a third segment sidewall directly connecting the second mesa and a side surface of the substrate.

In an embodiment, the semiconductor stack further includes a third segment sidewall connecting the second mesa and the first surface of the substrate.

In an embodiment, the semiconductor laser element further includes an insulation layer formed on the semiconductor stack. The insulation layer includes a first portion on the first mesa, a second portion on the second mesa, and a third portion connecting the first portion and the second portion.

In an embodiment, a thickness of the third portion first increases and then decreases in a direction from the first portion toward the second portion.

In an embodiment, the third portion has a maximum thickness and a minimum thickness, the maximum thickness is located above the connection surface, and the minimum thickness is located below the connection surface.

In an embodiment, the third portion has a maximum thickness greater than the width of the connection surface.

In an embodiment, the third portion has a minimum thickness less than a thickness of the first portion or the second portion.

In an embodiment, an angle formed between the third portion and the second portion is a third angle, the third angle being greater than or equal to 70° and less than or equal to 100°.

The disclosure provides yet another semiconductor laser element, includes: a substrate and a semiconductor stack.

The substrate has a first surface and a first side surface and a second side surface located on opposite sides of the substrate, and the first side surface and the second side surface extends along a first direction.

The semiconductor stack is formed on the first surface of the substrate, including a first semiconductor layer, an active layer, and a second semiconductor layer stacked sequentially. A ridge is formed on a surface of the second semiconductor layer, the ridge has an upper surface and a side surface adjacent to the upper surface, and the ridge extends along the first direction.

The semiconductor stack includes a first mesa connected to the side surface of the ridge and a second mesa adjacent to the first side surface or the second side surface of the substrate, the first mesa exposes a portion of a surface of the second semiconductor layer, and the second mesa exposes a portion of a surface of the first semiconductor layer.

The semiconductor stack further includes a first segment sidewall and a second segment sidewall, the first segment sidewall is connected to the first mesa, the second segment sidewall is connected to the second mesa, and a slope of the first segment sidewall is different from a slope of the second segment sidewall.

In an embodiment, at least one connection surface is included between the first segment sidewall and the second segment sidewall, such that the first segment sidewall and the second segment sidewall form discontinuous sidewalls.

In an embodiment, the first segment sidewall and the second segment sidewall are located between the first mesa and the second mesa.

In an embodiment, the semiconductor stack further includes a third segment sidewall connecting the second mesa and the first side surface or the second side surface of the substrate.

In an embodiment, the semiconductor laser element further includes a first electrode electrically connected to the first semiconductor layer, and the first electrode is in contact with a second surface of the substrate.

In an embodiment, the first electrode has a main body part extending along the first direction and a plurality of branch-shaped structures extending along edges of the main body part.

In the embodiments of the disclosure, by providing the connection surface between the first mesa and the second mesa, the curved surface effect is disrupted between the connection surface and the second segment sidewall without compromising the coverage of the insulation layer on the sidewalls of the semiconductor stack, thereby avoiding the impact of the curved surface effect on the breakdown voltage of the semiconductor laser element.

### BRIEF DESCRIPTION OF DRAWINGS

Features and advantages of the disclosure will be more clearly understood by referring to the accompanying drawings, which are illustrative only and should not be construed as imposing any limitation on the disclosure.

FIG. 1 illustrates a top view of a semiconductor laser element according to an embodiment of the disclosure.

FIG. 2 illustrates a manufacturing flowchart of the semiconductor laser element according to the embodiment of the disclosure.

FIG. 3 illustrates a cross-sectional view taken along line I-I′ of FIG. 1.

FIG. 4 illustrates an enlarged schematic view of portion A in FIG. 3.

FIG. 5 illustrates an enlarged schematic view of portion A in FIG. 3.

### DETAILED DESCRIPTION OF EMBODIMENTS

The following describes embodiments of the disclosure through specific embodiments. Those skilled in the art can readily understand other advantages and efficacies of the disclosure from the content disclosed herein. The disclosure can also be implemented or applied through other different specific embodiments, and various details in this disclosure can be modified or changed based on different viewpoints and applications without departing from the spirit of the disclosure.

In the description of the disclosure, it should be noted that the terms “upper”, “lower”, “inner”, “outer”, etc., indicating orientation or positional relationships, are based on the orientation or positional relationships shown in the accompanying drawings, or the conventional placement orientation or positional relationships when a product of the disclosure is in use. These terms are used only to facilitate the description of the disclosure and simplify the description, and do not indicate or imply that the referred apparatus or element must have a specific orientation, be constructed, and operate in a specific orientation. Therefore, they should not be construed as limitations on the disclosure. Furthermore, the terms “first” and “second”, etc., are used only for distinguishing the description and cannot be understood as indicating or implying relative importance.

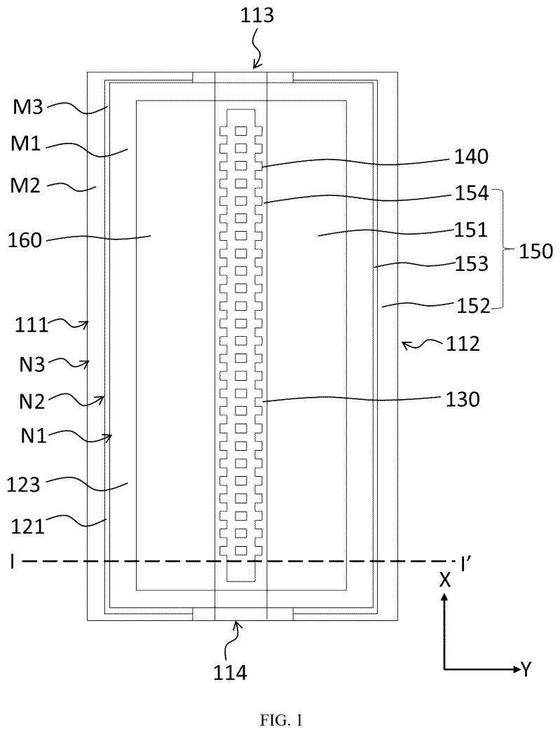

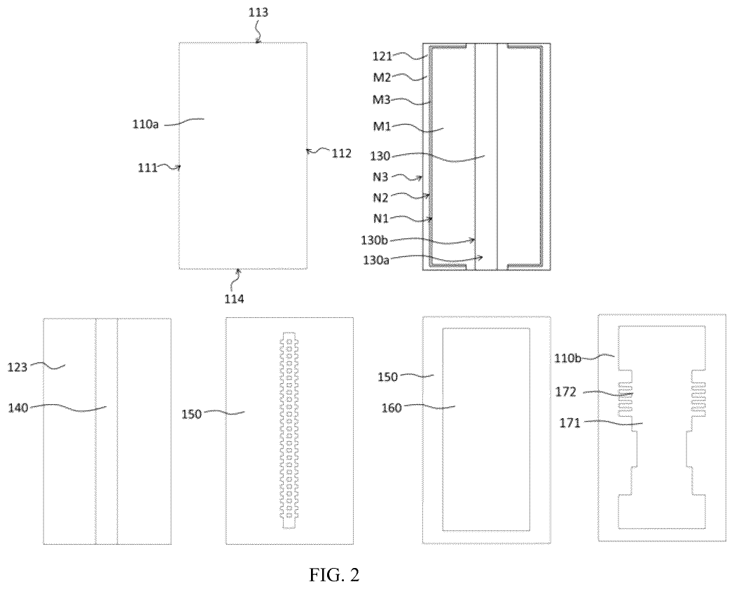

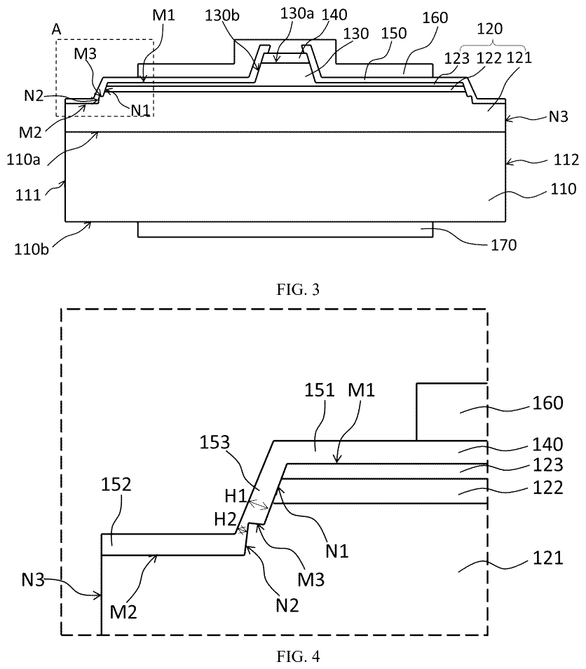

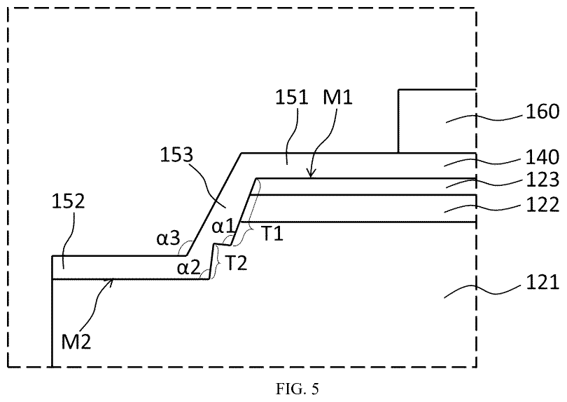

FIG. 1 is a top view of a semiconductor laser element according to an embodiment of the disclosure. FIG. 2 is a manufacturing flowchart of the semiconductor laser element according to the embodiment of the disclosure. FIG. 3 is a cross-sectional view taken along line I-I of FIG. 1. FIG. 4 and FIG. 5 are enlarged schematic views of portion A in FIG. 3.

As shown in FIG. 1, the semiconductor laser element includes a first direction X and a second direction Y, and the first direction X and the second direction Y are perpendicular to each other.

As shown in FIGS. 1 to 3, the semiconductor laser element includes a substrate 110. The substrate 110 includes a first surface 110a and a second surface 110b, located on upper and lower sides of the substrate 110, respectively. The substrate 110 further includes a first side surface 111, a second side surface 112, a third side surface 113, and a fourth side surface 114. The first side surface 111 and the second side surface 112 of the substrate 110 are located on two opposite sides of the substrate 110 and extend along the first direction X. The third side surface 113 and the fourth side surface 114 of the substrate 110 are located on the other two opposite sides and extend along the second direction Y. The first side surface 111, the second side surface 112, the third side surface 113, and the fourth side surface 114 constitute a periphery of the substrate 110.

In one embodiment, the semiconductor laser element may have a polygonal shape, such as triangular, hexagonal, rectangular, or square. As shown in FIG. 1, the dimensions of the semiconductor laser element can be, for example, 1200 micrometers (μm)×200 μm, 600 μm×200 μm, 600 μm×150 μm, 1200 μm×150 μm, 1100 μm×120 μm, 800 μm×200 μm, and 800 μm×150 μm, in a square or similarly sized rectangular shape, but is not particularly limited thereto.

The substrate 110 can be a growth substrate, including a nitride semiconductor, silicon carbide (SiC), or a high-resistance substrate such as a sapphire substrate. In one embodiment, the substrate 110 specifically includes a nitride semiconductor, and more specifically includes GaN. A substrate containing a nitride semiconductor has a higher thermal conductivity than sapphire, which can improve heat dissipation efficiency, thereby reducing defects such as dislocations and providing good crystallinity. Furthermore, the laser diode is specifically is grown on a C-plane of the nitride semiconductor substrate. Forming the laser diode on the C-plane of the nitride semiconductor allows cleavage planes (m-planes) to appear simply, and the C-plane is chemically stable, offering advantages such as ease of processing and sufficient etch resistance for subsequent processes. In another embodiment, the substrate 110 can be a support substrate. The original growth substrate used for epitaxially growing the semiconductor stack 120 can be selectively removed according to application needs, and the semiconductor stack 120 can then be transferred to the aforementioned support substrate.

In an embodiment, the thickness of the substrate 110 is, for example, at least 40 μm and/or at most 400 μm, specifically 50 μm, 60 μm, 80 μm, 100 μm, 120 μm, and 150 μm.

The semiconductor laser element includes a semiconductor stack 120 formed on the first surface 110a of the substrate 110. The semiconductor stack 120 includes a first semiconductor layer 121, an active layer 122, and a second semiconductor layer 123, sequentially disposed on the first surface 110a of the substrate 110.

In an embodiment, the semiconductor stack 120 is formed on the substrate 110 by metal organic chemical vapor deposition (MOCVD), molecular beam epitaxy (MBE), hydride vapor phase epitaxy (HVPE), physical vapor deposition (PVD), or an ion plating method.

In an embodiment, the first semiconductor layer 121 may include a buffer layer (not shown), a first cladding layer (not shown), and a first waveguide layer (not shown), which are sequentially disposed on the first surface 110a of the substrate 110.

The buffer layer is an n-type material layer made of a Group III-V nitride semiconductor based on GaN, or an undoped material layer. More specifically, for example, the buffer layer is an n-GaN layer, and silicon (Si) is suitable as the n-type dopant. In addition, a film thickness of the buffer layer is specifically, for example, from 100 nanometers (nm) to 2000 nm. The first cladding layer is formed on the buffer layer and consists of one or more GaN-based semiconductor layers doped with an n-type dopant. More specifically, for example, the first cladding layer can be composed of an n-type GaN layer, an n-type aluminum gallium nitride (AlGaN) layer, an n-type indium aluminum gallium nitride (InAlGaN) layer, etc., and Si is suitable as the n-type dopant. Furthermore, a film thickness of the first cladding layer is specifically, for example, from 500 nm to 3000 nm. The first waveguide layer is formed on the first cladding layer and consists of one or more GaN-based semiconductor layers. More specifically, for example, the first waveguide layer can be composed of an n-type GaN layer, an n-type InGaN layer, an n-type InAlGaN layer, etc. Alternatively, the first waveguide layer may be composed of an undoped GaN-based semiconductor layer, or the first waveguide layer may have a laminated structure composed of an n-type layer and an undoped layer. Furthermore, the film thickness of the first waveguide layer is specifically, for example, from 10 nm to 500 nm.

In an embodiment, the active layer 122 is formed on the first waveguide layer and has a structure where, for example, well layers (not shown) and barrier layers (not shown) composed of undoped GaN-based semiconductor layers are alternately arranged. More specifically, for example, the well layers and barrier layers can be composed of AlGaN layers, GaN layers, indium gallium nitride (InGaN) layers, InAlGaN layers, etc. Alternatively, the active layer (specifically, the barrier layer) may be composed of a GaN-based semiconductor layer doped with an n-type dopant. In this case, the bandgap of the barrier layer is set to a value larger than that of the well layer. Furthermore, the film thickness of each layer is specifically, for example, from 1 nm to 100 nm. The active layer may have a single quantum well structure including a single well layer, or may have a multi-quantum well structure where multiple well layers and multiple barrier layers are alternately arranged.

In an embodiment, the second semiconductor layer 123 includes a second waveguide layer, a carrier blocking layer (electron blocking layer), a second cladding layer, and a contact layer, which are sequentially disposed on the active layer.

The second waveguide layer is formed on the active layer 122 and consists of one or more GaN-based semiconductor layers. More specifically, for example, the second waveguide layer can be composed of a GaN layer, an InGaN layer, etc., and a p-type GaN-based semiconductor layer doped with magnesium (Mg) is suitable for the second waveguide layer. In addition, a film thickness of the second waveguide layer is specifically, for example, from 10 nm to 500 nm. The carrier blocking layer is formed on the second waveguide layer and consists of a GaN-based semiconductor layer doped with a p-type dopant. More specifically, for example, the carrier blocking layer can be composed of a p-type AlGaN layer, etc., and Mg is suitable as the p-type dopant. Furthermore, a film thickness of the carrier blocking layer is specifically, for example, from 5 nm to 100 nm. It should be noted that, in an embodiment of the disclosure, the carrier blocking layer may be formed between the active layer 122 and the second waveguide layer, or may be formed within the middle of the second waveguide layer. Additionally, a configuration where the carrier blocking layer is not provided in the semiconductor stack 120 may be adopted. Even without the carrier blocking layer, the function as the semiconductor laser element is maintained. The second cladding layer is formed on the carrier blocking layer and consists of one or more GaN-based semiconductor layers. More specifically, for example, the second cladding layer can be composed of a p-type GaN layer, a p-type AlGaN layer, a p-type InAlGaN layer, etc., and Mg is suitable as the p-type dopant. Furthermore, a film thickness of the second cladding layer is specifically, for example, from 100 nm to 1000 nm. The contact layer is formed on the second cladding layer and consists of a GaN-based semiconductor layer doped with a p-type dopant. More specifically, for example, the contact layer can be composed of a p-type GaN layer, and Mg is suitable as the p-type dopant. Furthermore, a film thickness of the contact layer is specifically, for example, from 5 nm to 100 nm.

As shown in FIGS. 1 to 3, a strip-shaped ridge 130 is formed on the upper surface of the second semiconductor layer 123, thereby enabling the formation of an effective refractive index-type waveguide. The ridge 130 extends along the first direction X. In an embodiment, selective etching is performed on the semiconductor stack 120 to form the ridge 130, a first mesa M1, a second mesa M2, and a connection surface M3 on the semiconductor stack 120. Specifically, the semiconductor stack 120 is processed by removing part of the second semiconductor layer 123 to form the ridge 130 and the first mesa M1 adjacent to the ridge 130. The semiconductor stack 120 is processed by removing parts of the second semiconductor layer 123, the active layer 122, and part of the first semiconductor layer 121 to form the second mesa M2 and the connection surface M3. As shown in FIGS. 1 to 5, the ridge 130 includes an upper surface 130a and a side surface 130b adjacent to the upper surface 130a. The upper surface of the ridge 130 is the surface of the second semiconductor layer 123 (i.e., the contact layer surface). The first mesa M1 exposes a portion of the surface of the second semiconductor layer 123. The second mesa M2 exposes a portion of the surface of the first semiconductor layer 121. The connection surface M3 exposes a portion of the surface of the first semiconductor layer 121. Taking the first surface 110a of the substrate 110 as a horizontal plane, the upper surface of the ridge 130 is higher than the portion of the second semiconductor layer 123 surface exposed by the first mesa M1. The portion of the second semiconductor layer 123 surface exposed by the first mesa M1 is higher than the portion of the first semiconductor layer 121 surface exposed by the connection surface M3. The portion of the first semiconductor layer 121 surface exposed by the connection surface M3 is higher than the portion of the first semiconductor layer 121 surface exposed by the second mesa M2. That is, the connection surface M3 is located between the first mesa M1 and the second mesa M2.

As shown in FIGS. 3 and 4, the semiconductor stack 120 includes a first segment sidewall N1, a second segment sidewall N2, and a third segment sidewall N3. The first segment sidewall N1 includes sidewalls formed by the second semiconductor layer 123, the active layer 122, and part of the first semiconductor layer 121. The second segment sidewall N2 includes a sidewall formed by part of the first semiconductor layer 121. The third segment sidewall N3 includes a sidewall formed by part of the first semiconductor layer 121. The third segment sidewall N3 is directly connected to the first side surface 111 of the substrate 110, or the third segment sidewall N3 is connected to an exposed portion of the first surface 110a of the substrate 110.

One end of the first mesa M1 is connected to the side surface 130b of the ridge 130, and the other end of the first mesa M1 is connected to the first segment sidewall N1. One end of the connection surface M3 is connected to the first segment sidewall N1, and the other end of the connection surface M3 is connected to the second segment sidewall N2. One end of the second mesa M2 is connected to the second segment sidewall N2, and the other end of the second mesa M2 is connected to the third segment sidewall N3. The connection surface M3 is located between the first segment sidewall N1 and the second segment sidewall N2, causing the first segment sidewall N1 and the second segment sidewall N2 to form a discontinuous sidewall structure. If a continuous structure were formed between the first segment sidewall N1 and the second segment sidewall N2 (without the presence of the connection surface M3), it might lead to poor coverage of the insulation layer 150 on the sidewalls of the semiconductor stack, as described below, particularly at the junction between the second segment sidewall N2 and the second mesa M2. Without the buffering effect of the connection surface M3 between the first segment sidewall N1 and the second segment sidewall N2, the insulation layer 150 might crack, affecting the reliability of the semiconductor laser element.

In an embodiment, the first segment sidewall N1 and the second segment sidewall N2 are located between the first mesa M1 and the second mesa M2, and the length T1 of the first segment sidewall is greater than the length T2 of the second segment sidewall. The second mesa M2 is used to define the size of the semiconductor laser element and the dicing street for cleavage. Therefore, a certain height is required between the first mesa M1 and the second mesa M2. In the embodiments of the disclosure, the height between the first mesa M1 and the second mesa M2 is greater than 2 μm. Since the first segment sidewall N1 and the second segment sidewall N2 are inclined, the total length of the first segment sidewall N1 and the second segment sidewall N2 will be greater than the height between the first mesa M1 and the second mesa M2. If the length T1 of the first segment sidewall is less than or equal to the length T2 of the second segment sidewall N2, it would result in an excessively long length T2 of the second segment sidewall, making it difficult to avoid the curved surface effect at the junction between the second segment sidewall N2 and the second mesa M2, which would affect the breakdown voltage of the semiconductor laser element. In an specifically embodiment, the length T2 of the second segment sidewall is less than 400 nm. A relatively short length T2 of the second segment sidewall makes it easier to avoid the curved surface effect at the junction between the second segment sidewall N2 and the second mesa M2.

In an embodiment, the ratio of T1 to T2 is greater than 5:1, and can specifically be 6:1, 8:1, 10:1, or 12:1. A larger ratio of T1 to T2, under a constant height between the first mesa M1 and the second mesa M2, helps to avoid the curved surface effect at the junction between the second segment sidewall N2 and the second mesa M2 as much as possible.

The width of the first mesa M1 affects the area of the second electrode 160 described below. The second mesa M2 is used to define the size of the semiconductor laser element and the dicing street for cleavage. Generally, the width of the second mesa M2 is adjusted according to the precision of the equipment. Therefore, in an embodiment of the disclosure, as shown in FIGS. 1 to 5, the width of the first mesa M1 is greater than the width of the second mesa M2, and the width of the second mesa M2 is greater than the width of the connection surface M3. The connection surface M3 is designed between the first segment sidewall N1 and the second segment sidewall N2, and its width is set to minimize the impact on the widths of the first mesa M1 and the second mesa M2. Otherwise, sacrificing the width of the first mesa M1 would reduce the area of the second electrode 160 described below, affecting the heat dissipation of the semiconductor laser element. Sacrificing the width of the second mesa M2 would affect the accuracy of wafer dicing for the semiconductor laser element. Therefore, in a specifically embodiment, the width of the connection surface M3 is less than 400 nm.

In an embodiment, the slopes of the first segment sidewall N1 and the second segment sidewall N2 are different. The absolute value of the slope of the first segment sidewall N1 is less than the absolute value of the slope of the second segment sidewall N2.

It should be noted that the slope of the sidewall in the embodiments of the disclosure is measured and calculated using the first surface 110a of the substrate 110 as the reference plane.

It should be noted that in the embodiments of the disclosure, an instance where the ridge 130 is formed by etching down into the second cladding layer is described. In addition, the ridge 130 can also be formed by etching down to a layer below the second cladding layer. In another possible implementation, it can be formed by etching from the second semiconductor layer 123 to part of the first semiconductor layer 121, forming a fully refractive index-type waveguide. Alternatively, the ridge 130 can also be formed by selective growth. The shape of the ridge 130 is not limited to a forward mesa shape where the width at the bottom side is wide and gradually narrows towards the top into a strip; conversely, it can be a reverse mesa shape where the width gradually narrows towards the bottom. Additionally, it can be a parallelepiped shape with sides perpendicular to the surface of the semiconductor stack 120, or a combination of the aforementioned shapes. Furthermore, the strip-shaped ridge 130 does not need to have a substantially uniform width.

As shown in FIGS. 1 to 3, an ohmic contact electrode 140 is formed on the upper surface 130a of the ridge 130, which can be prepared by methods such as sputtering, for example. Specifically, the main function of the ohmic contact electrode 140 is to improve lateral current spreading and expand the current action area. The material for the ohmic contact electrode 140 can be indium tin oxide (ITO), indium zinc oxide (IZO), zinc oxide (ZnO), gallium oxide (Ga₂O₃), etc. The material for the ohmic contact electrode 140 can also be metals such as nickel and gold.

As shown in FIGS. 1 to 4, an insulation layer 150 is formed on the semiconductor stack 120. The insulation layer 150 includes a first portion 151 covering the first mesa M1, a second portion 152 covering the second mesa M2, and a third portion 153 connecting the first portion 151 and the second portion 152. The thicknesses of the first portion 151 and the second portion 152 are approximately equal.

In an embodiment, in the direction from the first portion 151 to the third portion 153, the thickness of the third portion 153 first increases and then decreases. Due to the presence of the connection surface M3 between the first segment sidewall N1 and the second segment sidewall N2, the deposition of the third portion 153 of the insulation layer 150 along the sidewalls of the semiconductor stack has a buffering effect because of the connection surface M3. This allows the third portion 153 to provide good coverage on the sidewalls of the semiconductor stack 120. Furthermore, this thickness reaches a maximum near the connection surface M3 and then gradually decreases along the coverage on the second segment sidewall N2.

In an embodiment, the third portion 153 has a maximum thickness Hl and a minimum thickness H2. Using the connection surface M3 as a boundary, the area closer to the first mesa M1 is considered “above”, and the area closer to the second mesa M2 is considered “below”. The part of the third portion 153 with the maximum thickness H1 is located above the connection surface M3, and the part with the minimum thickness H2 is located below the connection surface M3.

In an embodiment, the minimum thickness H2 of the third portion 153 is less than the thickness of the first portion 151 or the second portion 152.

In an embodiment, the maximum thickness HI of the third portion 153 is greater than the width of the connection surface M3.

As shown in FIG. 4, using the first surface 110a of the substrate 110 as the horizontal plane, the height of the connection surface M3 is higher than the height of the junction between the second portion 152 and the third portion 153. That is, the thickness of the second portion 152 is less than the length T2 of the second segment sidewall N2. If the thickness of the second portion 152 is greater than the length T2 of the second segment sidewall N2, it would result in the insulation layer 150 being too thick, affecting the heat dissipation of the semiconductor laser element.

It should be noted that in the embodiments of the disclosure, the measurement standard for the thickness of the insulation layer 150 is: using the side surface or mesa covered by the insulation layer 150 (e.g., the first segment sidewall N1, the first mesa M1) as the reference surface, measure the thickness of the insulation layer perpendicular to this reference surface.

As shown in FIG. 5, the angle between the first segment sidewall N1 and the connection surface M3 is a first angle α1, and the angle between the second segment sidewall N2 and the second mesa M2 is a second angle α2, and the first angle α1 is different from the second angle α2. In an embodiment of the disclosure, the first angle α1 is greater than or equal to the second angle α2. If the first angle α1 is less than the second angle α2, it would cause the thickness of the third portion 153 of the insulation layer 150 covering the second segment sidewall N2 to be too thin, posing a risk of cracking.

In an embodiment, the first angle α1 is greater than or equal to 90°, and the second angle α2 is greater than or equal to 80°.

In an embodiment, the angle difference between the first angle α1 and the second angle α2 is greater than 5°.

As shown in FIG. 5, the angle between the third portion 153 and the second portion 152 is a third angle α3.

In an embodiment, the third angle α3 is greater than or equal to 70°.

In an embodiment, the third angle α3 is less than or equal to 100°.

In an embodiment, the obtuse angle between the first segment sidewall N1 and the first surface 110a of the substrate 110 is a fourth angle, and the obtuse angle between the second segment sidewall N2 and the first surface 110a of the substrate 110 is a fifth angle. When the connection surface M3 is parallel to the first surface 110a of the substrate 110, the fourth angle is equal to the first angle α1, and the fifth angle is equal to the second angle α2. Since the sidewall between the first mesa M1 and the second mesa M2 is mainly constituted by the first segment sidewall N1, the fourth angle affects the coverage of the insulation layer 150 deposited thereon. Specifically, the fourth angle is greater than 90°.

In an embodiment, the fourth angle is greater than the fifth angle.

The insulation layer 150 further includes a fourth portion 154 covering the side surface 130b of the ridge 130 and formed above the ridge 130, ensuring insulation between the exposed surface of the second semiconductor layer 123 on the first mesa M1 adjacent to the ridge 130 and the side surface 130b of the ridge, and providing a refractive index difference relative to the second semiconductor layer 123. The part of the insulation layer 150 located above the ridge 130 has an opening exposing the ohmic contact electrode 140.

For the insulation layer 150, for example, an insulating material containing one or more of silicon dioxide (SiO₂), SiN, aluminum oxide (Al₂O3), and zirconium dioxide (ZrO₂) is suitable. The film thickness of the insulation layer is specifically, for example, from 100 nm to 500 nm.

As shown in FIGS. 1-5, the insulation layer 150 covers the entire side surface of the ohmic contact electrode 140. In another embodiment, the insulation layer 150 may be formed to cover only a portion of the side surface of the ohmic contact electrode 140.

The second electrode 160 is formed on the ridge 130 and contacts the ohmic contact electrode 140 through the opening in the insulation layer 150, thereby being electrically connected to the second semiconductor layer 123. The region where the second electrode 160 is formed is not limited to the upper surface of the ridge 130; it can also extend onto the first mesa M1 over the insulation layer 150. The material for the second electrode 160 can include, for example, any one or more of palladium (Pd), platinum (Pt), nickel (Ni), gold (Au), titanium (Ti), tungsten (W), copper (Cu), silver (Ag), zinc (Zn), tin (Sn), indium (In), aluminum (Al), iridium (Ir), rhodium (Rh), or ITO.

A first electrode 170 is formed on the second surface of the substrate 110 and is electrically connected to the first semiconductor layer 121.

As shown in FIGS. 1-5, the first electrode 170 includes a main body part 171 extending along the first direction X and branch-shaped structures 172 extending along both sides of the main body part 171.

In an embodiment, the material of the first electrode 170 includes any one or a combination of two or more from Ni, Ti, Pd, Pt, Au, Al, TiN, ITO, and indium gallium zinc oxide (IGZO), etc., and is not limited thereto.

Furthermore, using the strip direction of the ridge 130 as the resonator direction, a pair of resonator facets provided on the end faces can be formed by cleavage or etching, etc. When forming by cleavage, the substrate 110 or the semiconductor stack 120 needs to have cleavability. Utilizing its cleavability allows easy obtaining of excellent mirror facets. Additionally, even without cleavability, the resonator facets can be formed by etching. The resonator facets formed by cleavage or etching may also be coated with a single-layer or multi-layer reflective film to efficiently reflect light from the active layer 122. One resonator facet is constituted by a relatively high reflectivity surface, primarily functioning as the resonator facet on the light reflection side that reflects light back into the waveguide region. The other resonator facet is constituted by a relatively low reflectivity surface, primarily functioning as the resonator facet on the light emission side that emits light to the outside.

What is claimed is:

1. A semiconductor laser element, comprising:
a substrate, having a first surface, a first side surface, and a second side surface located on opposite sides of the substrate, and the first side surface and the second side surface extending along a first direction; and
a semiconductor stack, formed on the first surface of the substrate, comprising a first semiconductor layer, an active layer, and a second semiconductor layer sequentially stacked, wherein a ridge is formed on a surface of the second semiconductor layer, the ridge has an upper surface and a side surface adjacent to the upper surface, and the ridge extends along the first direction;
wherein the semiconductor stack further comprises a first mesa connected to the side surface of the ridge and a second mesa adjacent to the first side surface or the second side surface of the substrate, the first mesa exposes a portion of a surface of the second semiconductor layer, and the second mesa exposes a portion of a surface of the first semiconductor layer; and
wherein the semiconductor stack further comprises a connection surface exposing another portion of the surface of the first semiconductor layer, a first segment sidewall, and a second segment sidewall; the first segment sidewall is located between the first mesa and the connection surface, the second segment sidewall is located between the second mesa and the connection surface, and a length of the first segment sidewall is greater than or equal to a length of the second segment sidewall.

2. The semiconductor laser element as claimed in claim 1, wherein a ratio of the length of the first segment sidewall to the length of the second segment sidewall is greater than 5:1.

3. The semiconductor laser element as claimed in claim 1, wherein an angle between the first segment sidewall and the connection surface is a first angle α1, an angle between the second segment sidewall and the second mesa is a second angle α2, and the first angle α1 is different from the second angle α2.

4. The semiconductor laser element as claimed in claim 3, wherein the first angle α1 is greater than or equal to the second angle α2.

5. The semiconductor laser element as claimed in claim 3, wherein the first angle α1 is greater than or equal to 90°, and the second angle α2 is greater than or equal to 80°.

6. A semiconductor laser element, comprising:
a substrate, having a first surface, a first side surface, and a second side surface located on opposite sides of the substrate, the first side surface and the second side surface extending along a first direction; and
a semiconductor stack, formed on the first surface of the substrate, comprising a first semiconductor layer, an active layer, and a second semiconductor layer sequentially stacked, wherein a ridge is formed on a surface of the second semiconductor layer, the ridge has an upper surface and a side surface adjacent to the upper surface, and the ridge extends along the first direction;
wherein the semiconductor stack further comprises a first mesa connected to the side surface of the ridge and a second mesa adjacent to the first side surface or the second side surface of the substrate, the first mesa exposes a portion of a surface of the second semiconductor layer, and the second mesa exposes a portion of a surface of the first semiconductor layer; and
wherein the semiconductor stack further comprises a connection surface exposing another portion of the surface of the first semiconductor layer, a first segment sidewall, and a second segment sidewall, the first segment sidewall is located between the first mesa and the connection surface, the second segment sidewall is located between the second mesa and the connection surface, an angle between the first segment sidewall and the connection surface is a first angle α1, an angle between the second segment sidewall and the second mesa is a second angle α2, and the first angle α1 is different from the second angle α2.

7. The semiconductor laser element as claimed in claim 6, wherein taking a second surface of the substrate as a horizontal plane, the upper surface of the ridge is higher than the first mesa, and the first mesa is higher than the second mesa.

8. The semiconductor laser element as claimed in claim 6, wherein taking a second surface of the substrate as a horizontal plane, a height of the connection surface is between a height of the first mesa and a height of the second mesa.

9. The semiconductor laser element as claimed in claim 6, wherein a width of the first mesa is greater than a width of the second mesa, and the width of the second mesa is greater than a width of the connection surface.

10. The semiconductor laser element as claimed in claim 6, wherein the semiconductor stack further comprises a third segment sidewall connecting the second mesa and the first side surface or the second side surface of the substrate.

11. The semiconductor laser element as claimed in claim 6, further comprising an insulation layer formed on the semiconductor stack, the insulation layer comprising a first portion on the first mesa, a second portion on the second mesa, and a third portion connecting the first portion and the second portion.

12. The semiconductor laser element as claimed in claim 11, wherein a thickness of the third portion first increases and then decreases in a direction from the first portion toward the second portion.

13. The semiconductor laser element as claimed in claim 11, wherein the third portion has a maximum thickness and a minimum thickness, the maximum thickness is located above the connection surface, and the minimum thickness is located below the connection surface.

14. The semiconductor laser element as claimed in claim 11, wherein an angle formed between the third portion and the second portion is a third angle, and the third angle is greater than or equal to 70° and less than or equal to 100°.

15. A semiconductor laser element, comprising:
a substrate, having a first surface, a first side surface, and a second side surface located on opposite sides of the substrate, the first side surface and the second side surface extending along a first direction; and
a semiconductor stack, formed on the first surface of the substrate, comprising a first semiconductor layer, an active layer, and a second semiconductor layer sequentially stacked, wherein a ridge is formed on a surface of the second semiconductor layer, the ridge has an upper surface and a side surface adjacent to the upper surface, and the ridge extends along the first direction;
wherein the semiconductor stack comprises a first mesa connected to the side surface of the ridge and a second mesa adjacent to the first side surface or the second side surface of the substrate, the first mesa exposes a portion of a surface of the second semiconductor layer, and the second mesa exposes a portion of a surface of the first semiconductor layer; and
wherein the semiconductor stack further comprises a first segment sidewall and a second segment sidewall, the first segment sidewall is connected to the first mesa, the second segment sidewall is connected to the second mesa, and a slope of the first segment sidewall is different from a slope of the second segment sidewall.

16. The semiconductor laser element as claimed in claim 15, wherein at least one connection surface is included between the first segment sidewall and the second segment sidewall, making the first segment sidewall and the second segment sidewall form discontinuous sidewalls.

17. The semiconductor laser element as claimed in claim 15, wherein the first segment sidewall and the second segment sidewall are located between the first mesa and the second mesa.

18. The semiconductor laser element as claimed in claim 15, wherein the semiconductor stack further comprises a third segment sidewall connecting the second mesa and the first side surface or the second side surface of the substrate.

19. The semiconductor laser element as claimed in claim 15, further comprising a first electrode electrically connected to the first semiconductor layer, the first electrode being in contact with a second surface of the substrate.

20. The semiconductor laser element as claimed in claim 19, wherein the first electrode has a main body part extending along the first direction and a plurality of branch-shaped structures extending along edges of the main body part.
